(19) United States
(12) Patent Application Publication
(10) Pub. No.: US 2025/0215738 A1
(43) Pub. Date: Jul. 3, 2025

(54) LOAD PORT AND CONTROL METHOD

(71) Applicant: HIRATA CORPORATION, Kumamoto-shi (JP)

(72) Inventors: Noriyoshi TOYODA, Kumamoto-shi (JP); Hiroki TAKAJO, Kumamoto-shi (JP)

(73) Assignee: HIRATA CORPORATION, Kumamoto-shi (JP)

(21) Appl. No.: 19/083,612

(22) Filed: Mar. 19, 2025

Related U.S. Application Data
(63) Continuation of application No. PCT/JP2023/043329, filed on Dec. 4, 2023.

(51) Int. Cl. E05F 15/73

(52) U.S. Cl. CPC E05F 15/73; E05Y 2900/11

(57) ABSTRACT

A load port includes a placing table on which a container for a substrate; a port plate including an opening portion; a port door configured to be capable of opening and closing the opening portion and holding a door portion of the container; a substrate detecting unit provided in the port door and configured to detect the substrate in the container; a lifting and lowering unit configured to lift and lower the port door; an advancing and retreating unit configured to advance and retreat the port door in an advancing and retreating direction; and a displacing unit configured to displace the substrate detecting unit in the advancing and retreating direction. The displacing unit displaces the substrate detecting unit in a direction opposite to the port door during an advancing and retreating operation of the port door by the advancing and retreating unit.

### CROSS-REFERENCE TO RELATED APPLICATION(S)

This application is a Continuation of International Patent Application No. PCT/JP2023/043329, filed Dec. 4, 2023, the entire disclosure of which is incorporated herein by reference.

### BACKGROUND OF THE INVENTION

### Field of the Invention

The present invention relates to a load port and a control method.

### Description of the Related Art

A known container is, for example, a Front-Opening Unified Pod (FOUP) that accommodates a substrate such as a semiconductor wafer. Such a container is opened and closed in a load port included in a substrate transport apparatus, and the internal substrate is taken in and out. After the door portion of the container is opened, the substrate in the container is detected by a sensor in order to confirm the presence of the substrate in the container (Japanese Patent No. 4246420 and Japanese Patent No. 6455239). The sensor may be referred to as a mapping sensor. The load port of Japanese Patent No. 6455239 has a configuration in which a door portion 22 and mapping sensors m1 and m2 move in a horizontal direction D and an up-down direction H. When the door portion 22 is at a fully closed position (C), the mapping sensors m1 and m2 are arranged at positions where interference with a frame 21 does not occur.

The deposition positions of the mapping sensors m1 and m2 of Japanese Patent No. 6455239 protrude in a direction away from the accommodating container than the door portion (See FIGS. 20 and 22). When the door portion 22is moved to a retreated position in the direction (the horizontal direction D) of separating from the accommodating container in order to open a lid portion of the accommodating container, the mapping sensors m1 and m2 also move together with the door portion 22. An extra space is required as much as the mapping sensors m1 and m2 have protruded.

### SUMMARY OF THE INVENTION

An object of the present invention is to provide a load port in which protrusion of a sensor for detecting a substrate is suppressed when a port door is in a retreated position.

According to an aspect of the present invention, there is provided a load port comprising: a placing table on which a container accommodating a substrate is placed; a port plate including an opening portion through which the substrate can be taken in and out; a port door configured to be capable of opening and closing the opening portion and holding a door portion of the container; a substrate detecting unit provided in the port door and configured to detect the substrate accommodated in the container; a lifting and lowering unit configured to lift and lower the port door with respect to the opening portion; an advancing and retreating unit configured to advance and retreat the port door in an advancing and retreating direction, which is a horizontal direction, with respect to the opening portion; and a displacing unit configured to displace the substrate detecting unit in the advancing and retreating direction, wherein the displacing unit displaces the substrate detecting unit in a direction opposite to the port door during an advancing and retreating operation of the port door by the advancing and retreating unit.

Further features of the present invention will become apparent from the following description of exemplary embodiments (with reference to the attached drawings).

### BRIEF DESCRIPTION OF THE DRAWINGS

FIG. 1 is an external view of a load port according to an embodiment of the present invention installed in a substrate transport apparatus.

FIG. 2 is a view showing an internal mechanism of the load port and the substrate transport apparatus of FIG. 1.

FIG. 3 is a plan view of an advancing and retreating unit.

FIG. 4 is a perspective view of a port door and a mapping unit.

FIG. 5 is an explanatory view of a turning mechanism.

FIG. 6 is a cross-sectional view taken along line A-A of FIG. 5.

FIG. 7 is an explanatory view of an operation of the mapping unit.

FIG. 8 is an explanatory view of an operation of the load port of FIG. 1.

FIG. 9 is an explanatory view of an operation of the load port of FIG. 1.

FIG. 10 is an explanatory view of an operation of the load port of FIG. 1.

FIG. 11 is an explanatory view of an operation of the load port of FIG. 1.

FIG. 12 is a timing chart showing changes in positions of the port door and the mapping sensor.

### DESCRIPTION OF THE EMBODIMENTS

Hereinafter, embodiments will be described in detail with reference to the attached drawings. Note that the following embodiments are not intended to limit the scope of the claimed invention, and limitation is not made to an invention that requires all combinations of features described in the embodiments. Two or more of the multiple features described in the embodiments may be combined as appropriate. Furthermore, the same reference numerals are given to the same or similar configurations, and redundant description thereof is omitted.

### Outline of Apparatus

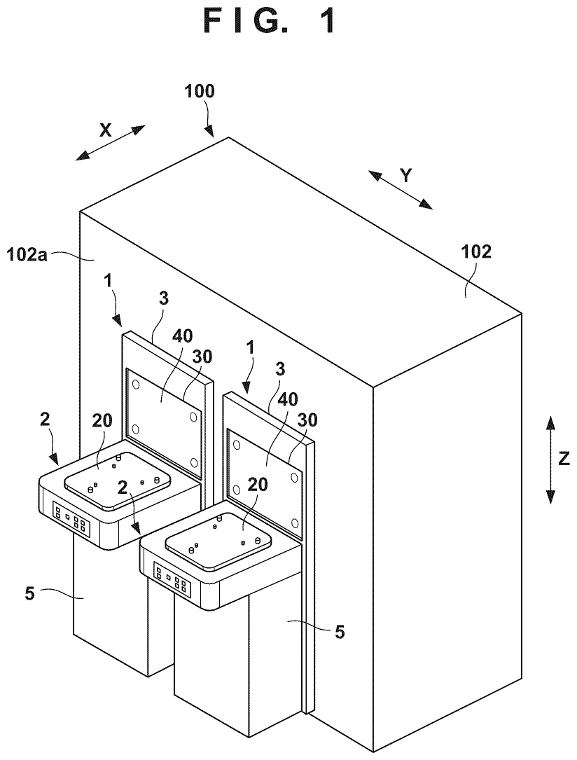

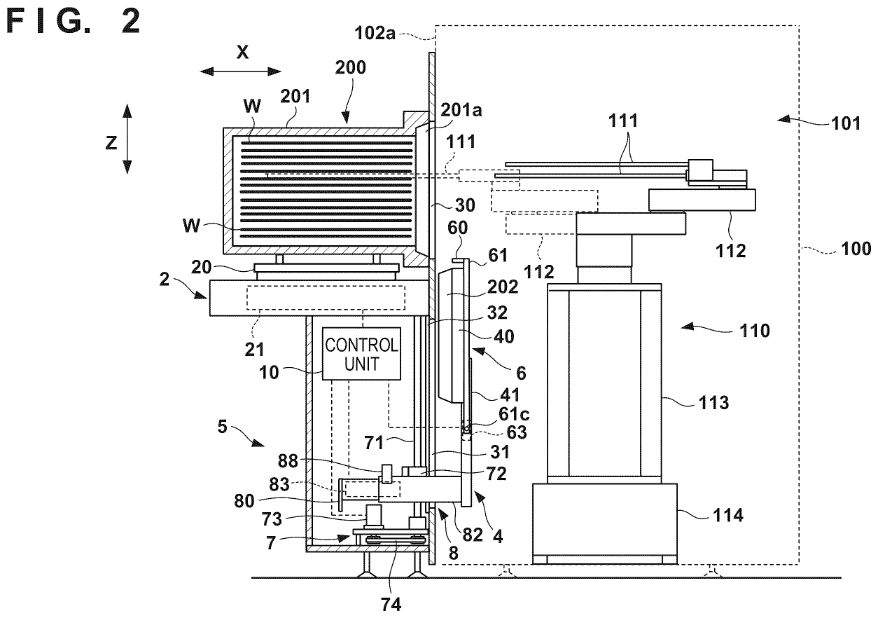

FIG. 1 is an external view of a load port 1 according to an embodiment of the present invention, and shows an aspect in which the load port 1 is installed in a substrate transport apparatus 100. FIG. 2 is a view showing an internal mechanism of the load port 1 and the substrate transport apparatus 100, and is a schematic cross-sectional view when a container 200 is placed on the load port 1. In each drawing, arrows X and Y indicate horizontal directions orthogonal to each other, and arrow Z indicates an up-down direction.

The load port 1 is a device that opens and closes the container 200 such as a FOUP. The container 200 includes: a box-shaped container main body 201 that has an opening portion 201a on a side for taking in and out a circular substrate W such as a semiconductor wafer; and a door portion 202 that is detachably attached to the opening portion 201a and closes the opening portion 201a, and accommodates the substrate W. FIG. 2 shows a state in which the door portion 202 is removed from the container main body 201 by the load port 1, and a substrate transport robot 110 can access the substrate W in the container 200.

The load port 1 is attached to the substrate transport apparatus 100 having the substrate transport robot 110 for transporting the substrate W therein. The substrate transport apparatus 100 includes a housing 102 that accommodates the substrate transport robot 110. The load port 1 is attached to a front wall 102a of the housing 102. In the example of FIG. 1, two load ports 1 are attached to the front wall 102a. The substrate transport robot 110 carries the substrate W out of and into the container 200 placed on the load port 1.

The substrate transport robot 110 includes an end effector 111 that holds the substrate W, an articulated arm 112 that holds the end effector 111 such that it can freely move at least forward and backward, and a driving unit 113 that allows the articulated arm 112 to pivot and move up and down. The substrate transport robot 110 further includes a traveling unit 114 that reciprocates the substrate transport robot 110 in a Y direction. As indicated by a broken line in FIG. 2, the end effector 111 of the substrate transport robot 110 is caused to enter the inside of the container main body 201 in which the opening portion 201a is opened to the side of the substrate transport apparatus 100, whereby the substrate W is carried out and carried in.

The load port 1 includes a placing table 2 on which the container 200 is placed, a port plate 3, a port door 4, a support portion 5 that supports the placing table 2, and a mapping unit 6. The port plate 3 is a plate-shaped wall extending in a Z direction, and closes an opening portion formed in the front wall 102a to partition an external space on the side of the placing table 2 and a transport space 101 of the substrate W in the substrate transport apparatus 100 together with the front wall 102a. In terms of the partition wall, the port plate 3 can also be said to be a member forming a part of the front wall 102a. The port plate 3 includes an opening portion 30 through which the detached door portion 202 and the end effector 111 can pass in an X direction.

The placing table 2 includes a dock plate 20 on which the container 200 is placed. The dock plate 20 is provided with a plurality of positioning pins (kinematic pins) that support the container 200 while positioning it, a seat sensor that detects the presence of the container 200, a lock mechanism that locks the container 200 placed on the dock plate 20 to the dock plate 20, and the like. The placing table 2 incorporates a driving mechanism 21 that displaces the dock plate 20 in the X direction.

The support portion 5 is a rectangular parallelepiped-shaped hollow body. The support portion 5 is provided with a lifting and lowering unit 7 that lifts and lowers the port door 4 with respect to the opening portion 30, and an advancing and retreating unit 8 that advances and retreats the port door 4 in an advancing and retreating direction with respect to the opening portion 30 (X direction in this embodiment). In this embodiment, the port door 4 is supported by the advancing and retreating unit 8, and the lifting and lowering unit 7 lifts and lowers the port door 4 by lifting and lowering the advancing and retreating unit 8.

In this embodiment, the lifting and lowering unit 7 is a ball screw mechanism. However, another driving mechanism may be used. The lifting and lowering unit 7 includes a ball screw shaft 71, a slider 72, a motor 73 as a driving source, and a belt transmission mechanism 74. The ball screw shaft 71 extends in the Z direction and is rotatably supported by the port plate 3. The ball screw shaft 71 is connected to the belt transmission mechanism 74 on the lower end side. The slider 72 has an engaging portion that engages with a rail member 32, and can reciprocate in the Z direction by the guide of the rail member 32. The rail member 32 extends in the Z direction and is supported by the port plate 3.

The belt transmission mechanism 74 includes a driven pulley connected to the ball screw shaft 71, a drive pulley connected to an output shaft of the motor 73, and an endless belt wound around these pulleys. The rotational force of the motor 73 is transmitted to the ball screw shaft 71 via the belt transmission mechanism 74, and the ball screw shaft 71 rotates. The rotation of the ball screw shaft 71 causes the slider 72 to move up and down.

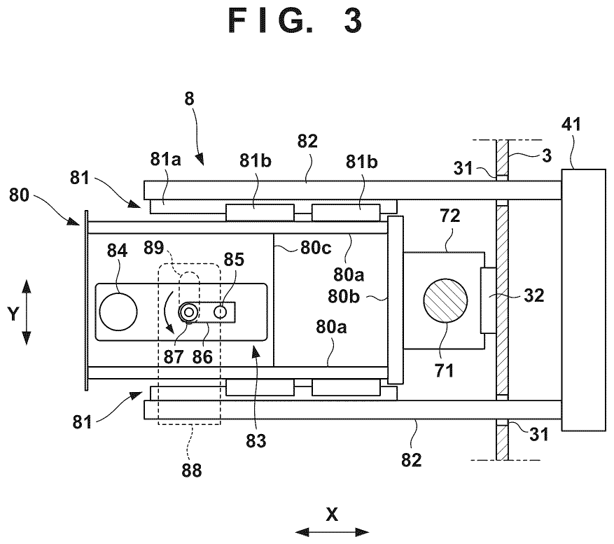

The advancing and retreating unit 8 will be described with reference to FIG. 3 in addition to FIG. 2. FIG. 3 is a plan view of the advancing and retreating unit 8. The advancing and retreating unit 8 is disposed below the placing table 2 and includes a body frame 80, a linear guide 81, a pair of moving bodies 82, and a driving mechanism 83. The body frame 80 includes a pair of side plates 80a separated in the Y direction, an end plate 80b on the side of the port plate 3 connecting the pair of side plates 80a, and a bottom plate 80c connecting the pair of side plates 80a. An end plate 80b is fixed to the slider 72, and the advancing and retreating unit 8 is lifted and lowered by moving the slider 72 up and down.

A pair of moving bodies 82 are plate-shaped arm members, and extend in the X direction through a pair of slits 31 of the port plate 3. The pair of slits 31 extend in the Z direction. A support portion 41 of the port door 4 is fixed to ends of the pair of moving bodies 82 in the X direction. The respective moving bodies 82 are supported by the corresponding side plates 80a via the linear guide 81, and are displaceable in the X direction. The linear guide 81 includes a rail member 81a fixed to the moving bodies 82 and a plurality of sliders 81b fixed to the side plates 80a. The plurality of sliders 81b is engaged with the rail member 81a extending in the X direction. The rail member 81a can reciprocate in the X direction by the guide of the sliders 81b.

The driving mechanism 83 is a cam mechanism that is provided on the bottom plate 80c and moves the pair of moving bodies 82 in the X direction. The driving mechanism 83 includes a motor 84 as a driving source, a rotary shaft 85, an arm member 86, a roller 87, and a cam member 88. The rotary shaft 85 is a shaft member extending in the Z direction, is connected to an output shaft of the motor 84 via a transmission mechanism (not illustrated, for example, a belt transmission mechanism), and rotates about the Z axis by a driving force of the motor 84. The arm member 86 is fixed to the rotary shaft 85 at one end thereof, and rotation of the rotary shaft 85 causes the arm member 86 to turn about the rotary shaft 85 as a rotation center. The roller 87 rotatable about the Z-axis is supported at the other end of the arm member 86.

One end of the cam member 88 is an L-shaped member fixed to one of the pair of moving bodies 82, and a cam hole 89 is formed in the other end. The cam hole 89 is an oval opening portion. The roller 87 is inserted into the cam hole 89, and a peripheral surface of the roller 87 is in contact with an inner surface of the cam hole 89. The motor 84 is rotated, as a result of which the arm member 86 turns. The roller 87 performs a circular motion about the rotary shaft 85. When the roller 87 abuts on the inner surface of the cam hole 89, the moving bodies 82 are moved in the X direction while a relative position in the Y direction between the roller 87 and the cam hole 89 is changed. Thus, the port door 4 moves forward and backward in the X direction.

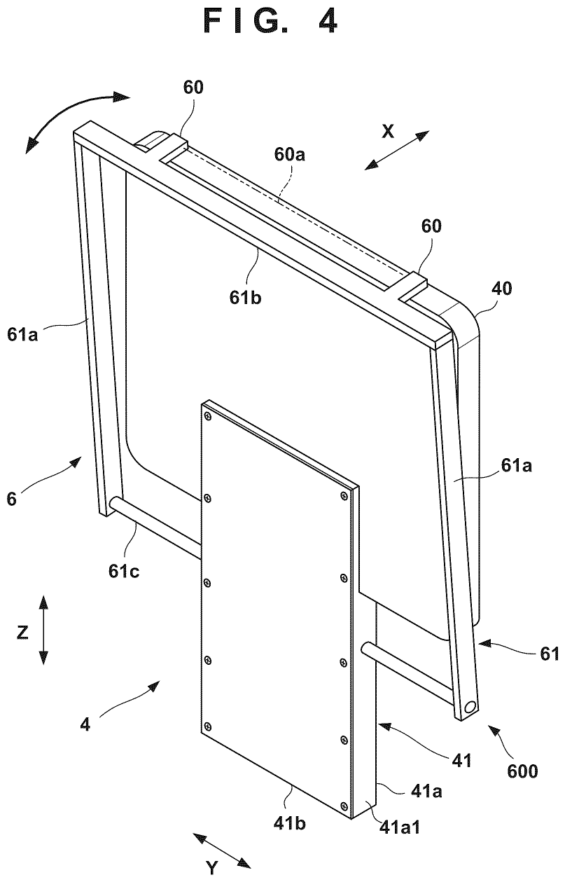

The port door 4 and the mapping unit 6 will be described with reference to FIG. 4 in addition to FIG. 2. FIG. 4 is a perspective view of the port door 4 and the mapping unit 6. The port door 4 includes a holding portion 40 that holds the door portion 202 and the support portion 41 that supports the holding portion 40. The holding portion 40 includes, for example, a chucking mechanism, and thus it is possible to chuck and hold the door portion 202. Further, the holding portion 40 is provided with an operation mechanism (latch key) that operates opening/closing of a lock mechanism included in the door portion 202. Thus, the container main body 201 and the door portion 202 can be detached and attached. The support portion 41 is a hollow body including a main body 41a and a cover member 41b and extending in the Z direction. The main body 41a is a box-shaped member in which the side of the substrate transport apparatus 100 (the side opposite to the placing table 2) is opened in the X direction, and the cover member 41b is detachably provided on the main body 41a so as to cover the opening of the main body 41a. In this embodiment, the cover member 41b is fixed to the main body 41a by a plurality of bolts.

The mapping unit 6 is a substrate detecting mechanism that is provided in the port door 4 and scans the substrate W in the container main body 201 in the Z direction when the port door 4 is lowered. The mapping unit 6 includes a pair of mapping sensors 60 that detect the substrate W accommodated in the container main body 201, and a displacement unit 600 that displaces the pair of mapping sensors 60 in the advancing and retreating direction of the port door 4 (the X direction in this embodiment).

In the case of this embodiment, the pair of mapping sensors 60 are optical sensors, and one of the pair of mapping sensors includes a light-emitting element and the other of the pair of mapping sensors includes a light-receiving element. An optical axis 60a in FIG. 4 indicates an optical axis of light from the light-emitting element toward the light-receiving element. During the scanning, the substrate W blocks the optical axis 60a, and thus the detection result of the light-receiving element changes. This enables the presence or absence and the position of the substrate W to be measured.

The displacement unit 600 includes a frame 61 that supports the pair of mapping sensors 60, and a turning mechanism 63 that is provided in the support portion 41 and allows the frame 61 to turn in the advancing and retreating direction of the port door 4 (X direction in this embodiment).

The frame 61 has a rectangular shape surrounding the holding portion 40 as a whole, and includes a pair of support columns 61a, a beam portion 61b, and a shaft portion 61c. The beam portion 61b is a rod-shaped member extending in the horizontal direction (the Y direction in this embodiment) intersecting the advancing and retreating direction of the port door 4 (the X direction in this embodiment). The pair of mapping sensors 60 are supported by the beam portion 61b to be separated from each other in the Y direction. The shaft portion 61c is a shaft member extending in parallel with the beam portion 61b, and is a rotation center of the frame 61 turned by the turning mechanism 63. The pair of support columns 61a are rod-shaped members that are separated from each other in the extending direction of the beam portion 61b (Y direction in this embodiment), and each extend in the Z direction. One end side (upper side) of the pair of support columns 61a is connected to the beam portion 61b, and the other end side (lower side) is connected to the shaft portion 61c.

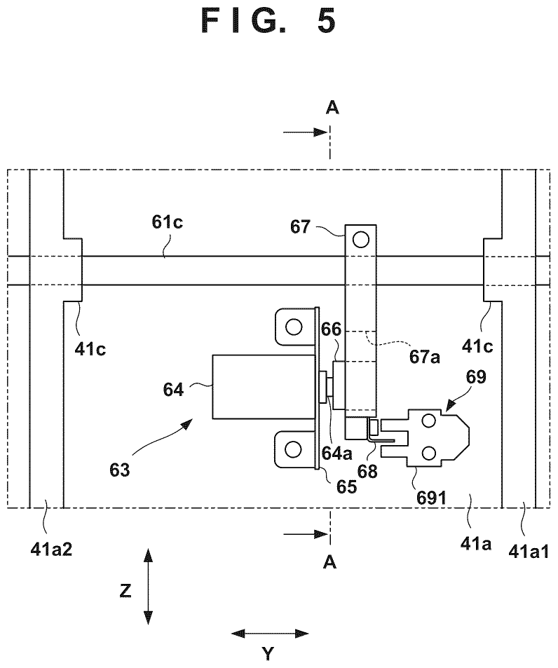

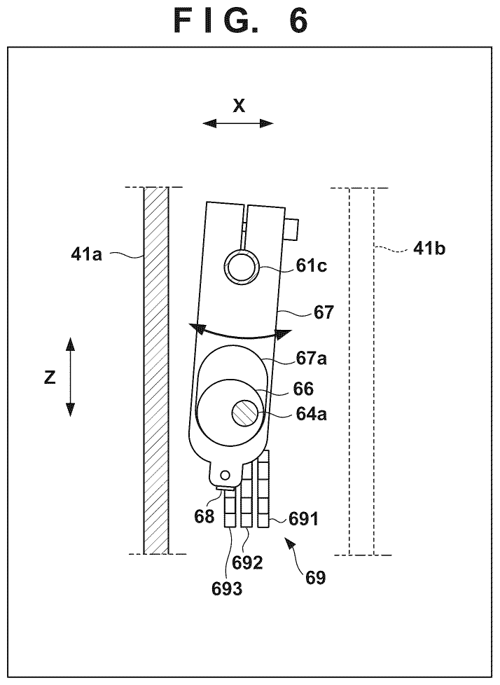

The turning mechanism 63 is a mechanism that allows the frame 61 to turn about the shaft portion 61c as a rotation center, and is disposed in the internal space of the support portion 41 formed by the main body 41a and the cover member 41b in this embodiment. Covering the turning mechanism 63 with the cover member 41b makes it possible to prevent, for example, dust of the turning mechanism 63 from flowing out to the outside. FIG. 5 is a view showing the turning mechanism 63 in the support portion 41, and showing a state in which the cover member 41b is removed. FIG. 6 is a cross-sectional view taken along line A-A of FIG. 5.

The main body 41a of the support portion 41 is provided with a pair of side portions 41a1 and 41a2. The pair of side portions 41a1 and 41a2 are plate-like members that are separated from each other in the horizontal direction (Y direction in this embodiment) and each extend in the Z direction. In the case of this embodiment, a hole through which the shaft portion 61c is inserted is formed in the pair of side portions 41a1 and 41a2, and bearing portions 41c that rotatably support the shaft portion 61c about the Y axis are formed in the pair of side portions 41a1 and 41a2. That is, the shaft portion 61c is rotatably supported about the Y axis by the bearing portions 41c integrally formed on the pair of side portions 41a1 and 41a2.

The turning mechanism 63 includes a motor 64 as a driving source, a cam member 66, and an arm member 67. The turning mechanism 63 further includes a position detection unit 69. The motor 64 is fixed to the main body 41a via a bracket 65. An output shaft 64a of the motor 64 extends in the Y direction and rotates around the Y axis. The cam member 66 has a columnar shape, and is an eccentric cam in which the output shaft 64a is fixed at a position deviated from the central axis thereof. The cam member 66 is rotated by driving of the motor 64. The motor 64 is fixed to the main body 41a via the bracket 65, and thus the turning mechanism 63 is supported by the support portion 41. In the support portion 41, a space where the turning mechanism 63 is disposed is formed by the main body 41a, the pair of side portions 41a1 and 41a2, and the cover member 41b.

Note that the member that rotatably supports the shaft portion 61c is not limited to the bearing portions 41c integrally formed on the pair of side portions 41a1 and 41a2, and may be provided in a space in which the turning mechanism 63 is disposed as a separate member from the pair of side portions 41a1 and 41a2.

The arm member 67 is a member having the shaft portion 61c fixed to one end side (upper end side) thereof and extending in a radial direction of the shaft portion 61c. A cam hole 67a is formed on the other end side (lower end side) of the arm member 67. The cam hole 67a is an opening portion having an oval cross section, and a peripheral surface of the cam member 66 is in contact with an inner surface of the cam hole. When the cam member 66 is rotated by driving of the motor 64, the shaft portion 61c is rotated while a relative position between the cam member 66 and the cam hole 67a is changed. Thus, the frame 61 turns about the shaft portion 61c as a rotation center.

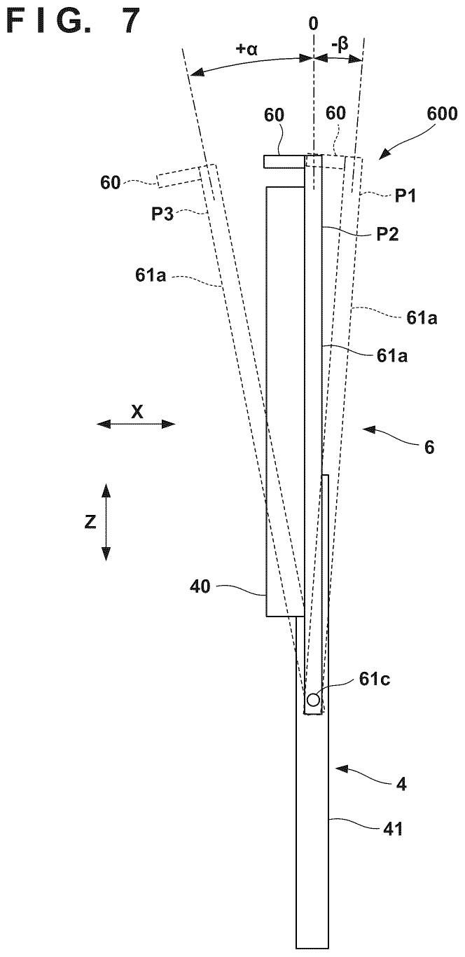

In the case of this embodiment, the frame 61 is turned at three positions as an example. FIG. 7 is an explanatory view of the example. In the relative position in the X direction of the mapping sensor 60 with respect to the port door 4, a position P1 is a position closest to the side of the transport space 101, a position P3 is a position closest to the side of the external space (position closest to the side of the container 200), and a position P2 is a position between the position P1 and the position P3.

The position P2 is a reference position for determining inclination angles of the position P1 and the position P3, and the inclination angle of the support column 61a in the X direction can be regarded as 0 degrees. That is, the support column 61a at the position P2 serves as an initial line for determining the inclination angles of the position P1 and the position P3. In this embodiment, the position P2 is a standby position where the support column 61a is in a vertical posture directed in the Z direction, and the inclination angle of the position P2 is 0 degrees. The mapping sensor 60 is located above the holding portion 40 of the port door 4.

The position P3 is a scanning position where the support column 61a takes an inclined posture inclined to the side of the external space (the side of the container 200) with respect to the position P2, and the inclination angle is +a degrees. The inclination angle on the side of the external space is positive and the inclination angle on the side of the transport space 101 is negative. One end side (upper end side) of the support column 61a is located on the side of the external space (the side of the container 200), and the mapping sensor 60 is located on the side of the external space (the side of the container 200) with respect to the holding portion 40 of the port door 4.

The position P1 is a retreated position where the support column 61a is in an inclined posture inclined to the side of the transport space 101 with respect to the position P2, and the inclination angle is −β degrees. One end side (upper end side) of the support column 61a is located on the side of the transport space 101, and the mapping sensor 60 is located on the side of the transport space 101 with respect to the holding portion 40 of the port door 4. In the case of this embodiment, as an example, a relationship of α>β is present.

Referring again to FIGS. 5 and 6, the position of the frame 61 is detected by the position detection unit 69. The position detection unit 69 is incorporated in the support portion 41 together with the turning mechanism 63. The position detection unit 69 of this embodiment includes a plurality of optical sensors 691 to 693 arranged in the X direction. The optical sensors 691 to 693 each are photointerrupters. A detection piece 68 is fixed to the other end side (lower end side) of the arm member 67. The position of the detection piece 68 in the X direction changes according to the turn of the arm member 67, i.e. the turn of the frame 61. The optical sensors 691 to 693 arranged in the X direction detect the detection piece 68 at different positions in the X direction. Thus, the position of the frame 61 can be identified from the detection result of the detection piece 68. In the case of this embodiment, the three positions P1 to P3 of the frame 61 illustrated in FIG. 7 are detected. Accordingly, the three optical sensors 691 to 693 are provided. Note that the configuration of the position detection unit 69 is an example, and the number, arrangement, or type of sensors can be designed, if appropriate.

Referring to FIG. 2, the load port 1 is provided with a control unit 10. The control unit 10 is an electronic circuit that controls the load port 1. The control unit 10 includes, for example, a processing unit represented by a CPU, storage units such as a RAM and a ROM, an input/output interface between an external device and the processing unit, and a communication interface that performs communication with a computer such as a host computer or a peripheral device (such as the substrate transport robot 110) via a communication line. The control unit 10 acquires, for example, detection results of various sensors and controls various driving sources. The various sensors include, for example, the mapping sensors 60, the optical sensors 691 to 693, a seat sensor of the dock plate 20, a sensor provided in the lifting and lowering unit 7, and a sensor provided in the advancing and retreating unit 8. The various driving sources include the motor 64, the motor 73, the motor 84, a driving source of the driving mechanism 21, a driving source of the holding portion 40, and the like.

### Example of Control

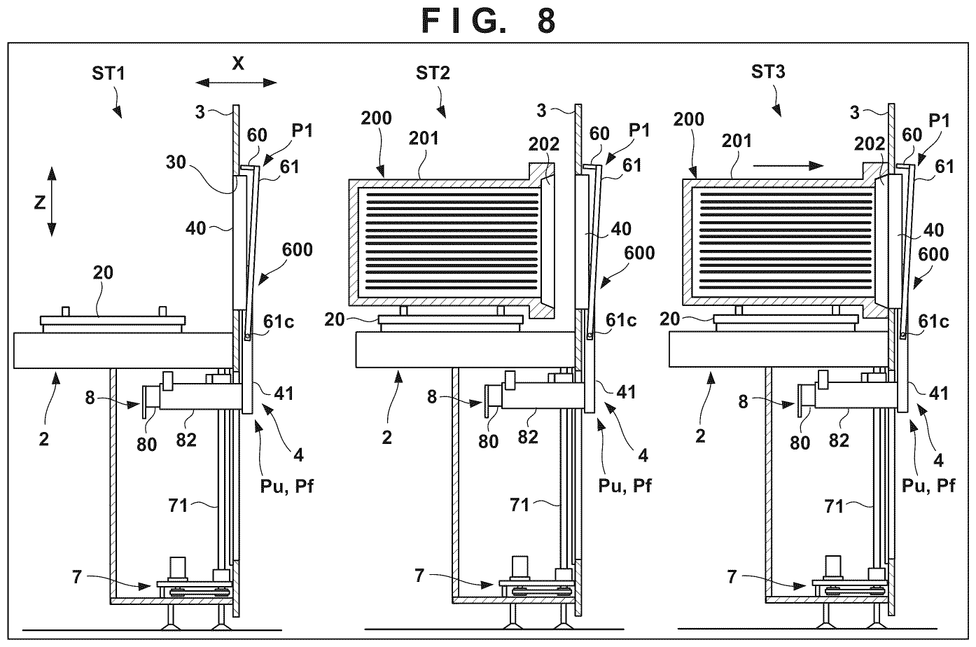

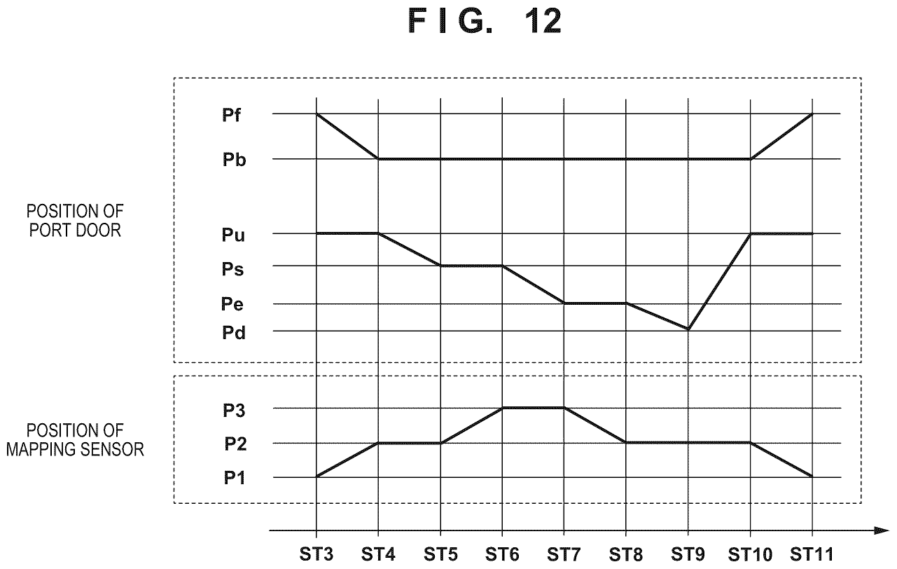

An example of control of the load port 1 by the control unit 10 will be described. FIGS. 8 to 11 show an example of the operation of the load port 1 under the control of the control unit 10, and particularly show an example of the control of an advancing and retreating operation of the port door 4 and a displacing operation of the mapping sensor 60 in a series of operations from the carry-in of the container 200, the opening of the container 200, the detection of the substrate W, and the closing of the container 200. FIG. 12 is a timing chart showing a transition of the positions of the port door 4 and the mapping sensor 60 in the series of operations shown in FIGS. 8 to 11.

In FIG. 12, the positions P1 to P3 of the mapping sensor 60 are the positions P1 to P3 shown in FIG. 7. Positions Pf and Pb of the port door 4 indicate positions of the port door 4 in the X direction, the position Pf is an advanced position on the side of the container 200, and the position Pb is a retreated position on the side of the transport space 101. Positions Pu, Ps, Pe, and Pd of the port door 4 indicate positions of the port door 4 in the Z direction. The position Pu is an attachment and detachment position where the holding portion 40 is located at the same height as the container 200 and the opening portion 30, and is an upper limit position of the port door 4. The position Pd is a standby position where the holding portion 40 is located lower than the container 200 and the opening portion 30, and is a lower limit position of the port door 4. The position Ps is a detection start position where the detection of the substrate W by the mapping sensor 60 is started, and is lower than the attachment and detachment position Pu and higher than the standby position Pd. The position Pe is a detection end position where the detection of the substrate W by the mapping sensor 60 ends, and is lower than the detection start position Ps and higher than the standby position Pd.

Refer to FIG. 8. A state ST1 indicates a stage before the container 200 is placed on the placing table 2. The dock plate 20 is located away from the port plate 3. The position of the port door 4 is the attachment and detachment position Pu and the advanced position Pf. The opening portion 30 is closed by the holding portion 40. The position of the mapping sensor 60 is the retreated position P1. In the retreated position P1, the mapping sensor 60 faces the port plate 3 above the opening portion 30. The mapping sensor 60 is located at the retreated position P1, thereby avoiding interference between the mapping sensor 60 and the port plate 3.

A state ST2 indicates a stage in which the container 200 is placed on the dock plate 20 of the placing table 2. The position of the port door 4 and the position of the mapping sensor 60 are the same as the positions in the state ST1. A state ST3 shows a stage in which the dock plate 20 has advanced with respect to the port plate 3 and the door portion 202 of the container 200 has been connected to the holding portion 40 of the port door 4. The position of the port door 4 and the position of the mapping sensor 60 are the same as the positions in the state ST1. The door portion 202 is held by the holding portion 40 from the side of the transport space 101, and the lock of the door portion 202 with respect to the container 200 is released.

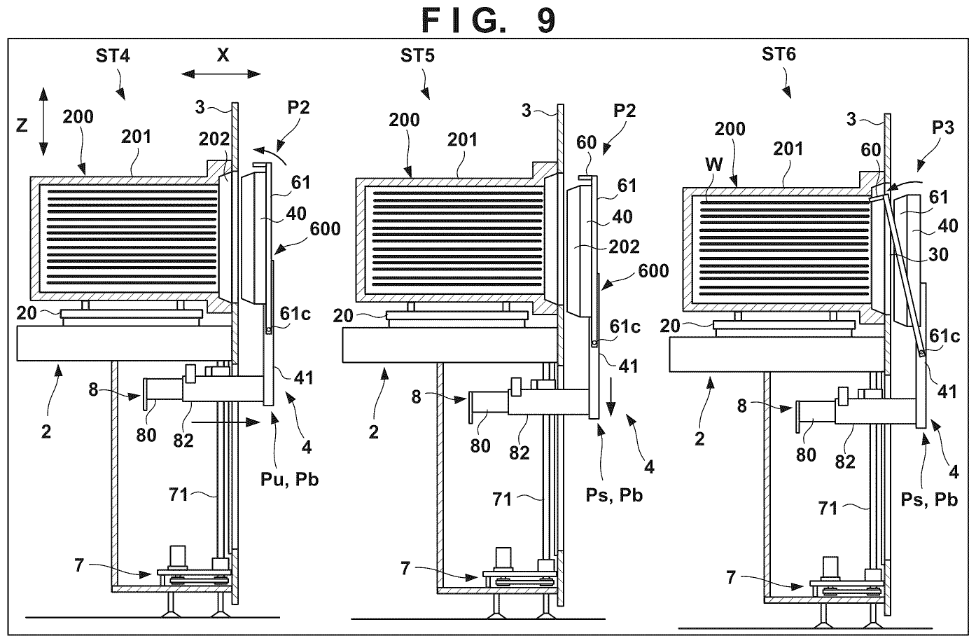

Refer to FIGS. 9 and 12. A state ST4 indicates a stage in which the door portion 202 is separated from the container main body 201 of the container 200, and the container 200 is opened. The advancing and retreating unit 8 retreats the port door 4 from the advanced position Pf to the retreated position Pb. During the retreating operation of the port door 4, the mapping sensor 60 is displaced in an opposite direction by the turning mechanism 63 and advances from the retreated position P1 to the standby position P2. The port door 4 and the mapping sensor 60 move to the side of the transport space 101 due to the retreating movement of the port door 4. Advancing the mapping sensor 60 from the retreated position P1 to the standby position P2 makes it possible to reduce the amount of entry of the mapping sensor 60 into the transport space 101 and to secure a wider transport space for the substrate transport robot 110. Therefore, when the port door 4 is in the retreated position, protrusions of the mapping sensor 60 and the frame 61 can be suppressed, and the influence of the mapping unit 6 on the transport space 101 can be reduced. Further, the mapping sensor 60 is advanced from the retreated position P1 to the standby position P2 during the retreating operation of the holding portion 40, thereby reducing the operation amount for displacing the mapping sensor 60 to be described later to the scanning position P3. Since the operation time for displacing the mapping sensor 60 to the scanning position P3 is shortened as compared with a case where the mapping sensor 60 is displaced from the retreated position P1 to the scanning position P3 after the retreating operation of the holding portion 40 is completed, the cycle time required for mapping can be shortened.

A state ST5 indicates a stage in which the lifting and lowering unit 7 lowers the port door 4 from the attachment and detachment position Pu to the detection start position Ps. During the lowering process, the mapping sensor 60 is maintained at the standby position P2. When the port door 4 is located at an inspection start position Ps, the position of the mapping sensor 60 is at the height of the opening portion 30 (more specifically, the height of the upper end of the opening portion 30 or less) in the up-down direction. A state ST6 indicates a stage in which the mapping sensor 60 is displaced from the standby position P2 to the scanning position P3 by the turning mechanism. The mapping sensor 60 enters the container 200 (container main body 201) from the opening portion 30. At this time, the optical axis 60a (FIG. 4) is at a position where the substrate W accommodated in the container 200 can be detected in the container 200.

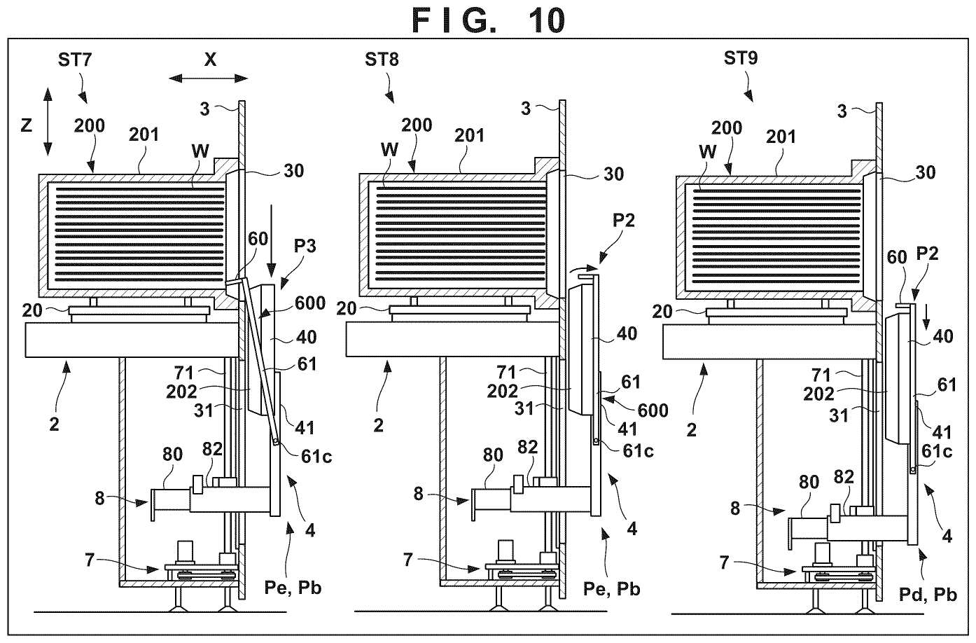

Refer to FIGS. 10 and 12. A state ST7 indicates a stage in which the lifting and lowering unit 7 has lowered the port door 4 from the detection start position Ps to the detection end position Pe. During the lowering process, the substrate W is detected from the side of the transport space 101 by the mapping sensor 60, and the detection result and the detection position are stored in the storage units of the control unit 10. A state ST8 indicates a stage in which the mapping sensor 60 is displaced from the scanning position P3 to the standby position P2 by the turning mechanism 63. The mapping sensor 60 is returned from the scanning position P3 to the standby position P2, thereby avoiding interference between the edge of the container main body 201 or the opening portion 30 and the mapping sensor 60. A state ST9 indicates a stage in which the lifting and lowering unit 7 has lowered the port door 4 from the detection end position Pe to the standby position Pd. The position of the mapping sensor 60 is the standby position P2. Thereafter, the substrate W is taken out by the substrate transport robot 110, the substrate W is processed by a processing apparatus (not illustrated), and the processed substrate W is accommodated in the container main body 201.

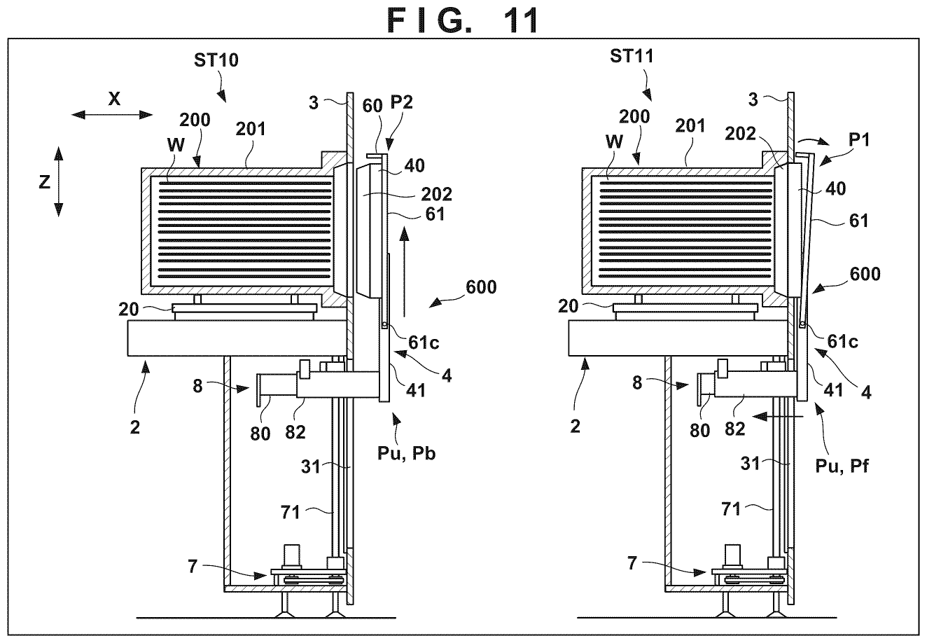

Refer to FIGS. 11 and 12. FIG. 11 shows an operation of closing the container 200 by attaching the door portion 202 to the container main body 201, and the operation is started from the position of the port door 4 and the mapping sensor 60 in the state ST9 of FIG. 10.

A state ST10 indicates a stage in which the port door 4 is lifted from the standby position Pd to the attachment and detachment position Pu by the lifting and lowering unit 7. During the lifting process, the mapping sensor 60 is maintained at the standby position P2. A state ST11 shows a stage in which the door portion 202 is attached to the container main body 201 of the container 200 to close the container 200. The advancing and retreating unit 8 advances the port door 4 from the retreated position Pb to the advanced position Pf. During the advancing operation of the port door 4, the mapping sensor 60 is displaced in an opposite direction by the turning mechanism 63 and retreats from the standby position P2 to the retraction position P1. Although the port door 4 and the mapping sensor 60 move to the side of the external space (the side of the container 200) by the advancing movement of the port door 4, it is possible to avoid the mapping sensor 60 from interfering with the port plate 3 above the opening portion 30 by retreating the mapping sensor 60 from the standby position P2 to the retraction position P1.

Thereafter, the door portion 202 is locked to the container main body 201 by the holding portion 40, and the holding of the door portion 202 is released. Thus, a series of operations is completed.

As described above, in this embodiment, the mapping sensor 60 is displaced in the direction opposite to the port door 4 in the X direction during the advancing and retreating operation of the port door 4 by the advancing and retreating unit 8. Accordingly, it is possible to intend to reduce the amount of entry of the mapping sensor 60 into the transport space 101 and prevent interference between the mapping sensor 60 and the port plate 3. Therefore, it is possible to provide the load port 1 with less influence on the transport space 101 of the substrate transport apparatus 100 and improved protection performance of the mapping sensor 60.

In this embodiment, the displacement unit 600 that displaces the pair of mapping sensors 60 in the advancing and retreating direction is provided in the support portion 41 that supports the holding portion 40 of the port door 4. Since the displacement unit 600 is provided in the support portion 41, it is possible to suppress an increase in size of the load port 1. Furthermore, disposing the turning mechanism 63 in the internal space of the support portion 41 makes it possible to downsize the displacement unit 600, and the occupied area of the mapping unit 6 can be saved. The lifting and lowering unit 7 lifts and lowers the mapping unit 6 together with the port door 4, but the amount of movement of the slider 72 required to open and close the container 200 is reduced due to the downsizing of the displacement unit 600 (particularly, suppression of downward protrusion of the port door 4). Therefore, the lifting and lowering unit 7 can be downsized.

The embodiments of the invention have been described above, The invention is not limited to the foregoing embodiments, and various variations/changes are possible within the spirit of the invention.

What is claimed is:

1. A load port comprising:
a placing table on which a container accommodating a substrate is placed;
a port plate including an opening portion through which the substrate can be taken in and out;
a port door configured to be capable of opening and closing the opening portion and holding a door portion of the container;
a substrate detecting unit provided in the port door and configured to detect the substrate accommodated in the container;
a lifting and lowering unit configured to lift and lower the port door with respect to the opening portion;
an advancing and retreating unit configured to advance and retreat the port door in an advancing and retreating direction, which is a horizontal direction, with respect to the opening portion; and
a displacing unit configured to displace the substrate detecting unit in the advancing and retreating direction,
wherein the displacing unit displaces the substrate detecting unit in a direction opposite to the port door during an advancing and retreating operation of the port door by the advancing and retreating unit.

2. The load port according to claim 1, wherein
the port plate partitions an external space on a side of the placing table and a transport space of the substrate, and
the port door holds the door portion of the container from a side of the transport space, and
the substrate detecting unit detects the substrate accommodated in the container from the side of the transport space.

3. The load port according to claim 2, wherein
when the door portion is separated from the container, the advancing and retreating unit retreats the port door from an advanced position on a side of the external space to a retreated position on the side of the transport space,
when the door portion is attached to the container, the advancing and retreating unit advances the port door from the retreated position to the advanced position,
the displacing unit displaces the substrate detecting unit to a first position during an advancing operation in which the port door is advanced from the retreated position to the advanced position, and displaces the substrate detecting unit to a second position during a retreating operation in which the port door is retreated from the advanced position to the retreated position, and
the second position is a position closer to the side of the external space than the first position in a relative position of the substrate detecting unit with respect to the port door.

4. The load port according to claim 3, wherein
the displacing unit displaces the substrate detecting unit to a third position closer to the side of the external space than the second position when the substrate detecting unit is at the height of the opening portion.

5. The load port according to claim 4, wherein
the third position is a position where the substrate detecting unit enters the opening portion.

6. The load port according to claim 3, wherein
the substrate detecting unit is disposed at a position higher than the port door, and
the first position and the second position are positions where the substrate detecting unit faces the port plate above the opening portion.

7. The load port according to claim 4, wherein
the port door includes:
a holding portion configured to hold the door portion; and
a support portion configured to support the holding portion,
the lifting and lowering unit lifts and lowers the support portion, and
the advancing and retreating unit advances and retreats the support portion, and
the displacing unit includes:
a frame configured to support the substrate detecting unit;
a turning mechanism provided in the support portion and configured to turn the frame in the advancing and retreating direction; and
a position detecting unit configured to detect a position of the frame.

8. The load port according to claim 7, wherein the frame includes:
a beam portion extending in a horizontal direction intersecting with the advancing and retreating direction; and
a shaft portion extending in the horizontal direction and configured to be inserted into the support portion; and
a pair of support columns separated from each other in an extending direction of the beam portion, one end side of the support columns being connected to the beam portion, and another end side of the support columns being connected to the shaft portion,
the substrate detecting unit is supported by the beam portion, and
the turning mechanism turns the frame about the shaft portion as a rotation center in the advancing and retreating direction, and
at the first position, the pair of support columns are in a first inclined posture in which the one end side is inclined so as to be located on the side of the transport space, and
at the third position, the pair of support columns are in a second inclined posture in which the one end side is inclined so as to be located on the side of the external space.

9. The load port according to claim 8, wherein in the second position, the pair of support columns are in a vertical posture.

10. The load port according to claim 8, wherein
the turning mechanism includes:
a driving source;
a cam member configured to rotate by the driving source; and
an arm member fixed to the shaft portion and extending in a radial direction of the shaft portion,
wherein an opening portion is formed in the arm member, the opening portion having an inner surface with which the cam member comes into contact, and the rotation of the cam member causes the arm member to turn about the shaft portion as a rotation center.

11. The load port according to claim 10, further comprising a detection piece provided in the arm member and configured to be detected by the position detecting unit,
wherein the position detecting unit includes a plurality of sensors arranged to detect the detection piece at different positions.

12. The load port according to claim 1, wherein
the lifting and lowering unit includes a first driving source,
the advancing and retreating unit includes a second driving source,
the displacing unit includes a third driving source,
the load port includes a control unit configured to control the first driving source, the second driving source, and the third driving source, and
the control unit controls the advancing and retreating operation of the port door and a displacing operation of the substrate detecting unit.

13. A load port, comprising:
a placing table on which a container which is capable of accommodating a substrate is placed;
a port plate including an opening portion through which the substrate can be taken in and out;
a port door capable of opening and closing the opening portion and holding a door portion of the container; and
substrate detecting unit that is provided in the port door and detects the substrate accommodated in the container;
lifting and lowering unit for lifting and lowering the port door with respect to the opening portion;
advancing and retreating unit for advancing and retreating the port door in an advancing and retreating direction as a horizontal direction with respect to the opening portion; and
displacing unit for displacing the substrate detecting unit in the advancing and retreating direction,
wherein the port door includes a holding portion that holds the door portion and a support portion that supports the holding portion,
the advancing and retreating unit includes a moving body that supports the support portion and moves in the advancing and retreating direction, and
the support portion is provided with the displacing unit,
the displacing unit includes:
a frame configured to support the substrate detecting unit; and
a turning mechanism configured to turn the frame in the advancing and retreating direction,
the support portion includes:
a box-shaped main body having an opening; and
a cover member configured to cover the opening of the main body, and
the turning mechanism is disposed in an internal space of the support portion formed by the main body and the cover member.

14. The load port according to claim 13, wherein
the frame includes a shaft portion as a rotation center, and
the support portion includes a bearing portion configured to rotatably support the shaft portion.

15. The load port according to claim 13, wherein
the frame includes:
a beam portion extending in a horizontal direction intersecting with the advancing and retreating direction and supporting the substrate detecting unit;
a shaft portion that extends in the horizontal direction and is inserted into the support portion; and
a pair of support columns separated from each other in an extending direction of the beam portion, one end side of the support columns being connected to the beam portion, and another end side of the support columns being connected to the shaft portion,
the turning mechanism includes:
a driving source;
a cam member that rotates by the driving source; and
an arm member fixed to the shaft portion and extending in a radial direction of the shaft portion,
an opening portion is formed in the arm member, the opening portion having an inner surface with which the cam member comes into contact, and the rotation of the cam member causes the arm member to turn about the shaft portion as a rotation center.

16. The load port according to claim 13, further comprising a control unit configured to control the load port,
wherein the turning mechanism includes a positon detection unit configured to detect a position of the frame, and
the control unit control the lifting and lowering unit and the displacing unit according to a detection result of the position detecting unit.

17. The load port according to claim 16, wherein
the position detection unit includes:
a first detection sensor configured to correspond to a reference position of the frame;
a second detection sensor configured to correspond to a position on one side with regard to the reference position; and
a third detection sensor configured to correspond to a position on the other side with regard to the reference position,
the control unit identifies whether the frame is at the reference position, the position on one side, or the position on the other side according to the detection result of the position detection unit.

18. A method for controlling a load port including: a placing table on which a container accommodating a substrate is placed; a port plate including an opening portion through which the substrate can be taken in and out; a port door configured to be capable of opening and closing the opening portion and holding a door portion of the container; and a substrate detecting unit provided in the port door and configured to detect the substrate accommodated in the container, the method comprising:
a lifting and lowering step of lifting and lowering the port door with respect to the opening portion;
an advancing and retreating step of advancing and retreating the port door in an advancing and retreating direction, which is a horizontal direction, with respect to the opening portion; and
a displacing step of displacing the substrate detecting unit in the advancing and retreating direction,
wherein in the displacing step, the substrate detecting unit is displaced in a direction opposite to the port door during an advancing and retreating operation of the port door by the advancing and retreating step.
